(19) United States
(12) Patent Application Publication
(10) Pub. No.: US 2018/0288901 A1
(43) Pub. Date: Oct. 4, 2018

(54) HEAT DISSIPATION DEVICE HAVING COMPACT VAPOR CHAMBER

(71) Applicant: DYNATRON CORPORATION, Union City, CA (US)

(72) Inventor: Tai-Chi HUANG, UNION CITY, CA (US)

(21) Appl. No.: 15/472,254

(22) Filed: Mar. 28, 2017

(51) Int. Cl. H05K 7/20; F28F 9/013

(52) U.S. Cl. CPC H05K 7/20309; F28F 2225/04; H05K 7/20327; F28F 9/0131

(57) ABSTRACT

A heat dissipation device having compact vapor chamber includes a vapor chamber, a supporting plate, a supporting frame, and heat dissipation members. The supporting plate is arranged on a surface of the vapor chamber and provided with a frame plate, an opening defined in the frame plate and multiple supporting ribs forming at a surrounding edge of the frame plate. The supporting rib is contacted with a surrounding edge of the vapor chamber, and a part of the vapor chamber is exposed through the opening. The supporting frame is contacted with the other surface of the vapor chamber opposite to the supporting rib. The supporting frame is extended from a side edge of the vapor chamber to the other side edge opposite thereto. The heat dissipation member is arranged on the supporting frame and contacted with the vapor chamber.

### BACKGROUND OF THE INVENTION

### Technical Field

The present disclosure relates to a heat dissipation device and, in particular, to a heat dissipation device having a vapor chamber.

### Description of Related Art

Accompanied with development of semi-conductor technology, operation speed of components in electronic products is greatly increased, and amount of heat generated thereby is also increased. Heat dissipation devices are therefore required for dissipating the heat to control a working temperature and maintain operations of the electronic components.

Moreover, a vapor chamber is a high-performance heat dissipation member which is able to rapidly conduct heat from a part of heat source to a plate with a large surface area. The vapor chamber with high heat transitivity, light weight, simple structure and multi-applicability is able to transfer large amount of heat without power consuming and therefore widely applied in high-performance heat dissipation component market, such as server, communication, high level graphic card, heat dissipation members of high performance LED.

On the other hand, compact vapor chambers are intended for current compact electronic devices. Accordingly, the vapor chamber tends to deformation while the vapor chamber is screw connected because of its weak structure, and a gap is therefore formed between the vapor chamber and a heat dissipated objection and a decreasing of efficiency of heat dissipation is therefore caused.

In views of this, in order to solve the above disadvantage, the present inventor studied related technology and provided a reasonable and effective solution in the present disclosure.

### SUMMARY

It is a purpose of the present disclosure to provide a heat dissipation device having a compact vapor chamber which a supporting force for preventing the vapor chamber from deformation resulting from weak structures and also preventing a gap therefore forming between the vapor chamber and a heat source member, so that efficiency of heat dissipation is maintained.

In order to achieve aforementioned purpose, a heat dissipation device including a compact vapor chamber, a supporting plate, a supporting frame and multiple heat dissipation members is provided in the present disclosure. The supporting plate is arranged on a surface of the vapor chamber and provided with a frame plate, an opening defined in the frame plate and multiple supporting ribs forming at a surrounding edge of the frame plate. The supporting rib is contacted with the surrounding edge of the vapor chamber, and a part of the vapor chamber is exposed through the opening. The supporting frame is contacted with the other surface of the vapor chamber opposite to the supporting rib. The supporting frame is extended from a side edge of the vapor chamber to the other opposite side edge thereof. The heat dissipation member is arranged on the supporting frame and contacted with the vapor chamber.

The heat dissipation device of the present disclosure is distinct from conventional technologies where the supporting plate and the supporting frame are arranged at respective surfaces opposite to each other of the vapor chamber. Wherein, the supporting plate is provided with a supporting rib contacted with the surrounding edge of the vapor chamber, the supporting frame is extended from a side edge of the vapor chamber to the other side edge to contact with the other surface of the vapor chamber opposite to the supporting rib. Accordingly, the vapor chamber is more firmly supported by the supporting plate supporting frame. Furthermore, supporting structures could be provided at bare holes of the heat dissipation device of the present disclosure and thereby prevent bolts from deformation and deflection resulted from weight pressure, and a gap forming between the vapor chamber and a heat source member resulted from a deformation of weak structure is thereby avoid, and a better efficiency of heat conduction is further maintained.

### BRIEF DESCRIPTION OF DRAWING

The present disclosure can be more fully understood by reading the following detailed description of the embodiment, with reference made to the accompanying drawings as follows:

FIG. 1 is a perspective view showing the heat dissipation device having compact vapor chamber of the present disclosure.

FIG. 2 is an exploded view showing a part of the heat dissipation device having compact vapor chamber of the present disclosure.

FIG. 3 is another exploded view showing another part of the heat dissipation device having compact vapor chamber of the present disclosure.

FIG. 4 is another perspective view showing another part of the heat dissipation device having compact vapor chamber of the present disclosure.

FIG. 5 is further another perspective view showing another part of the heat dissipation device having compact vapor chamber of the present disclosure.

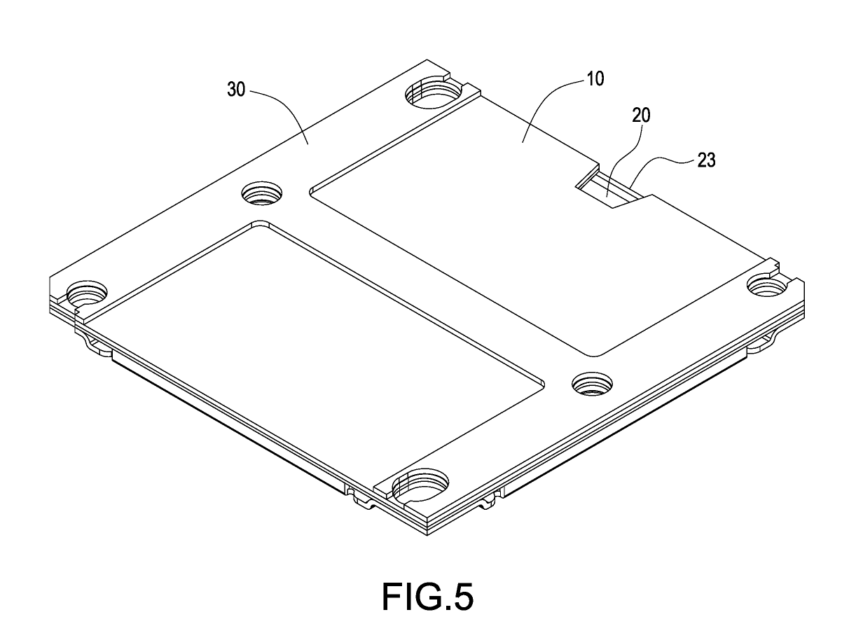

FIG. 6 is a cross sectional view showing another part of the assembled heat dissipation device having compact vapor chamber of the present disclosure.

FIG. 7 is another cross sectional view showing the assembled heat dissipation device having compact vapor chamber of the present disclosure.

FIG. 8 is further another cross sectional view showing the assembled heat dissipation device having compact vapor chamber of the present disclosure.

### DETAILED DESCRIPTION

Detail descriptions of the technology of the present disclosure are articulated below according to drawings. However, the drawings are only used for references and explaining, and the present disclosure should not be limited thereto.

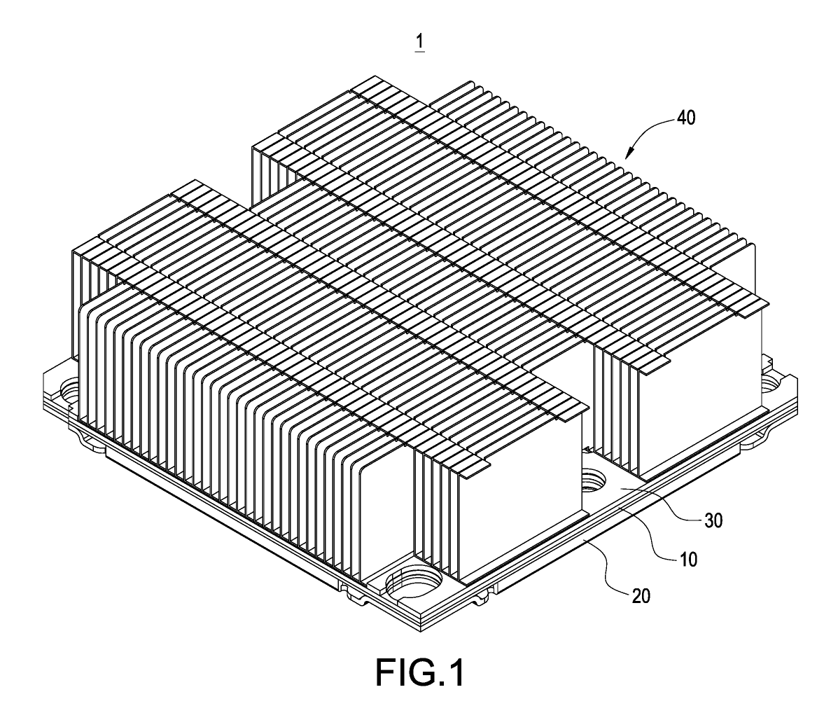

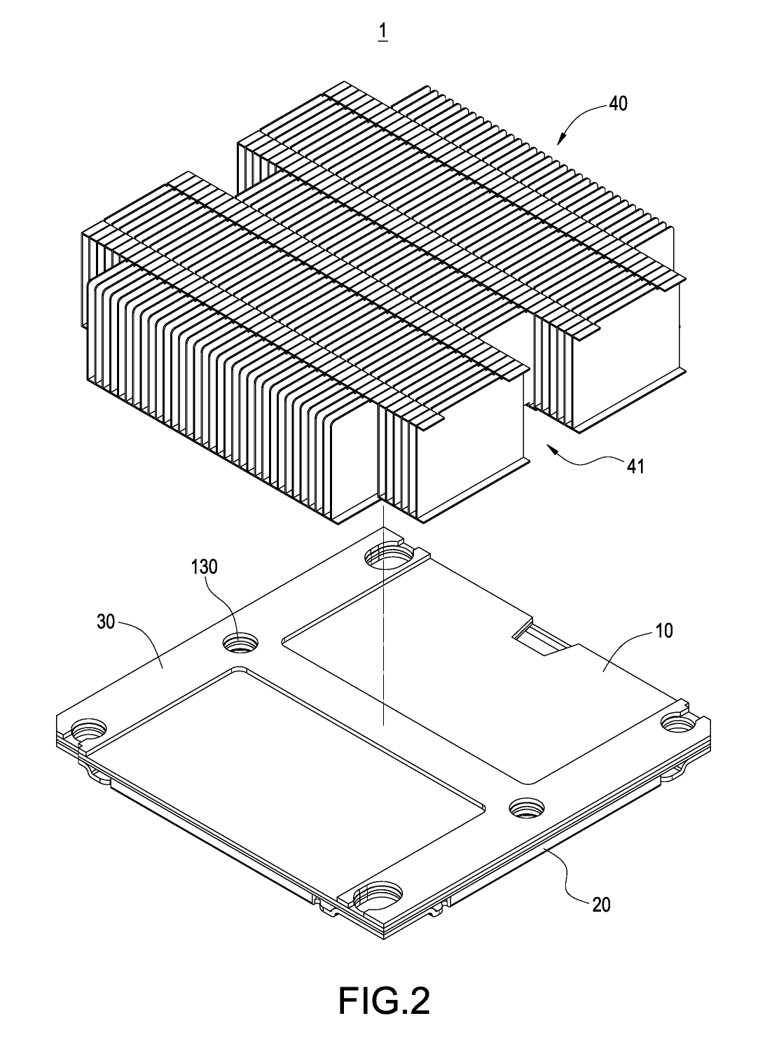

According to FIGS. 1 and 2 which are respectively a perspective view showing the heat dissipation device having compact vapor chamber of the present disclosure and an exploded view showing a part of the heat dissipation device having compact vapor chamber of the present disclosure. Accordingly, the heat dissipation device having compact vapor chamber 1 of the present disclosure includes a vapor chamber 10, a supporting plate 20, a supporting frame 30 and a heat dissipation member 40. respective of the supporting plate 20 and the supporting frame 30 are arranged on two surfaces of the vapor chamber 10 opposite to each other, the heat dissipation member 40 is combined on the supporting frame 30. In addition, a part of the vapor chamber 10 is exposed on from the supporting plate 20 for contacting with a heat source member (not shown in Figs.) to dissipate heat therefrom.

Accordingly, heat generated by the heat source member could be rapidly and uniformly conducted to the heat dissipation member 40 via the vapor chamber 10 and dissipated from a large heat dissipation area of the heat dissipation member 40. Preferably, the vapor chamber 10 is a compact vapor chamber, however the present disclosure should not be limited to the embodiment. Details of the heat dissipation device 1 are further described below. It is noted that, structures of the vapor chamber 10 are current technologies and not be claimed on the present disclosure, and redundant descriptions thereof are therefore not be recited.

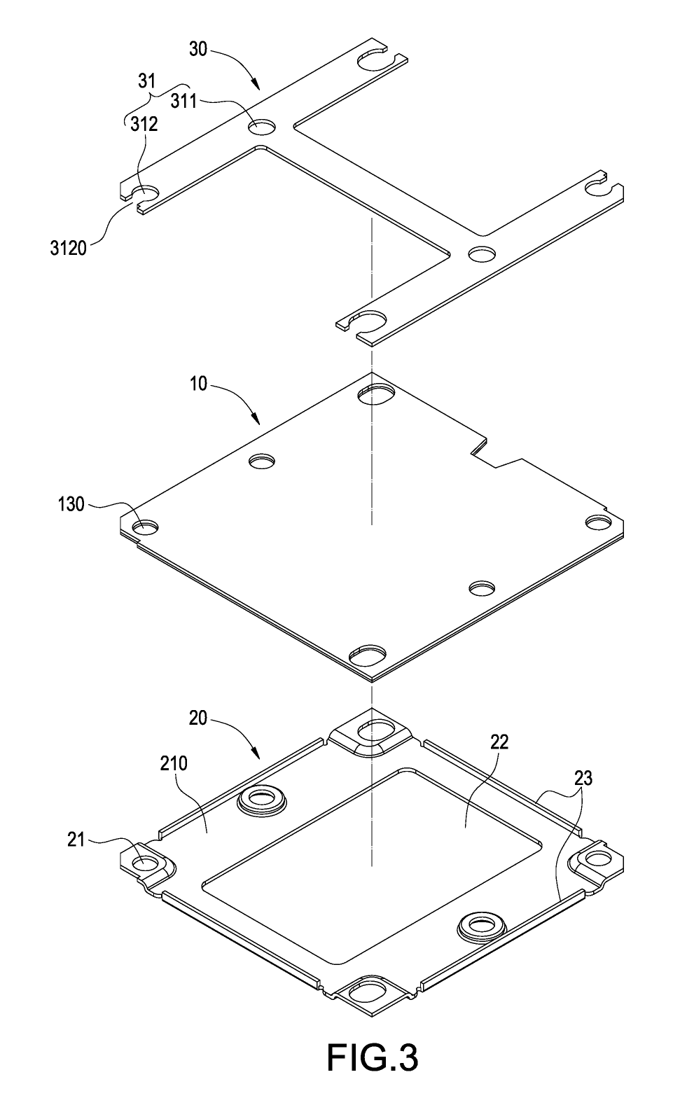

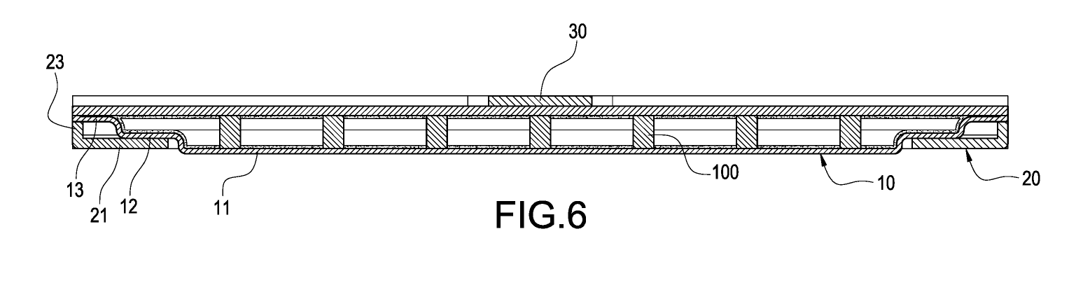

Further according to FIGS. 3 and 6 which are respectively another exploded view showing another part of the heat dissipation device having compact vapor chamber of the present disclosure and a cross sectional view showing another part of the assembled heat dissipation device having compact vapor chamber of the present disclosure. The supporting plate 20 is arranged on a surface of the vapor chamber 10, and the supporting frame 30 is arranged on the other surface of the vapor chamber 10. Moreover, the heat dissipation member 40 is arranged on the supporting frame 30 and contacted with the vapor chamber 10.

The supporting plate 20 is provided with a frame plate 21. An opening 22 is defined in the frame plate 21 and multiple supporting ribs 23 are formed at a surrounding edge of the frame plate 21. The supporting ribs 23 are contacted with the surrounding edge of the vapor chamber 10. Accordingly, the surrounding edge of the vapor chamber 10 could be more firmly supported by the supporting ribs 23, and the surrounding edge of the vapor chamber 10 is thereby prevented from deformation. In the present embodiment, the surrounding edge of the frame plate 21 is bent to form the supporting ribs 23, and the supporting ribs 23 are spaced apart from each other.

It is noteworthy that a part of the vapor chamber 10 is exposed through the opening 22 to contact with the heat source member.

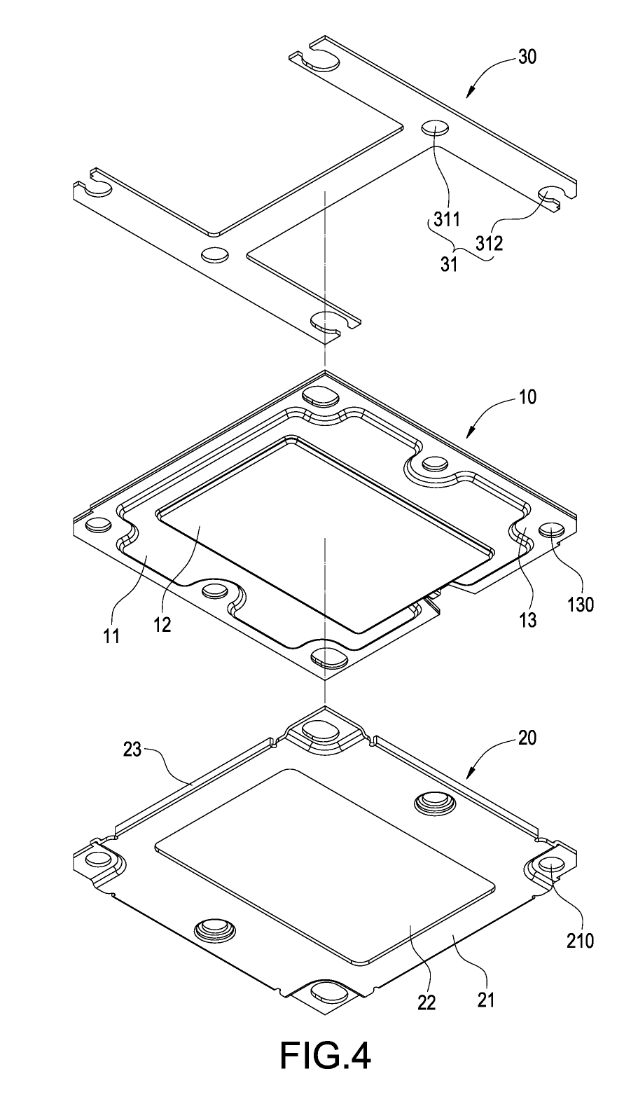

Moreover, the supporting frame 30 is contacted with the other surface of the vapor chamber 10 opposite to the supporting rib 23, and the supporting frame 30 is extended from a side edge of the vapor chamber 10 to another side edge opposite thereto. In the present embodiment, the supporting frame 30 is a frame of an “I” shape, but the present disclosure should not be limited to the embodiment, the supporting frame 30 could be of an “H” shape or other shapes. According to FIGS. 3 and 4, the vapor chamber 10 includes a surface of a step shape and contacted with the supporting plate 20 and a side of a flat surface shape contacted with the supporting frame 30. Furthermore, the vapor chamber 10 includes a first heat conductive portion 11, a second heat conductive portion 12 surrounding the first heat conductive portion 11 and a fixing portion 13 at and edge of the vapor chamber 10.

Specifically, the first heat conductive portion 11 exposes in the opening 22 of the supporting plate 20 for contacting with the heat source member. Heat is the vapor chamber 10 conducted to the heat dissipation member 40 via the first heat conductive portion 11. In addition, heat is conducted to the supporting plate 20 the vapor chamber 10 via the second heat conductive portion 12. The fixing portion 13 has a plurality of through hole 130, the through hole 130 allowing a plurality of screw fixing member to be insert (not shown in Figs.), and the vapor chamber 10 is thereby fixed. in the present embodiment, the heat dissipation member 40 is a heat dissipation fin stack, and a plurality of opened portion 41 is defined on the heat dissipation member 40 corresponding to positions of the through holes 130 of the vapor chamber 10 (according to FIG. 2).

Moreover, multiple first connecting holes 210 are defined on a surrounding edge of the supporting plate 20 at positions corresponding to the through holes 130 of the vapor chamber 10. Preferably, a protruding portion is formed on the surrounding edge of the supporting plate 20 at each position of the first connecting hole 210. In addition, multiple second connecting holes 31 are defined on the supporting frame 30 at positions corresponding to the through holes 130. In the present embodiment, the second connecting hole 31 include multiple circular holes 311 and multiple elongated openings 312, a breach gap 3120 is defined at a side of each the elongated hole 312, but the present disclosure should not be limited thereto.

It is noted that, the through holes 130 of the vapor chamber 10, the first connecting holes 210 of the supporting plate 20, the second connecting holes 31 of the supporting frame 30 and opened portions 41 of the heat dissipation member 40 are arranged align with each other for inserting screw fixing members therein to fix while the heat dissipation device 1 is assembled.

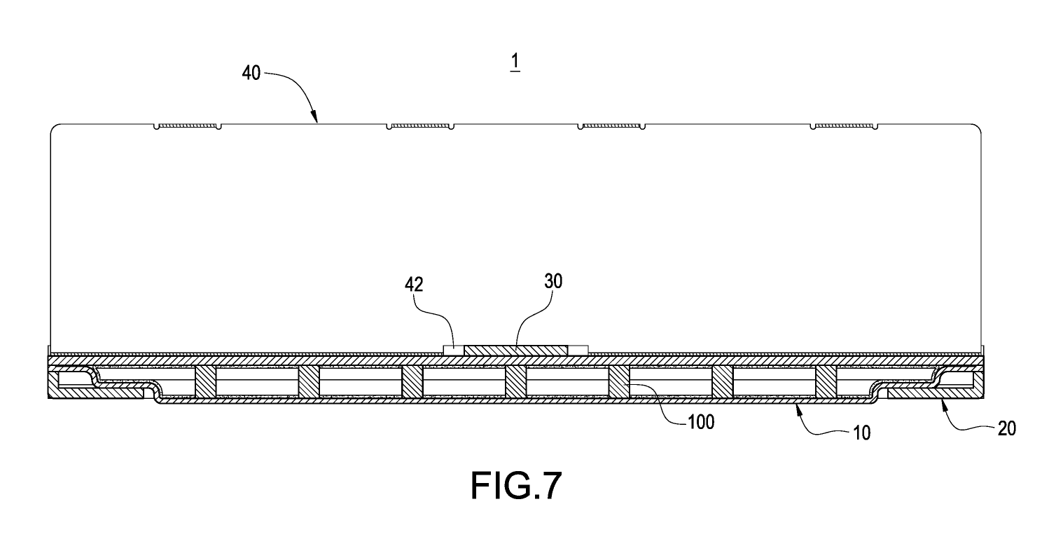

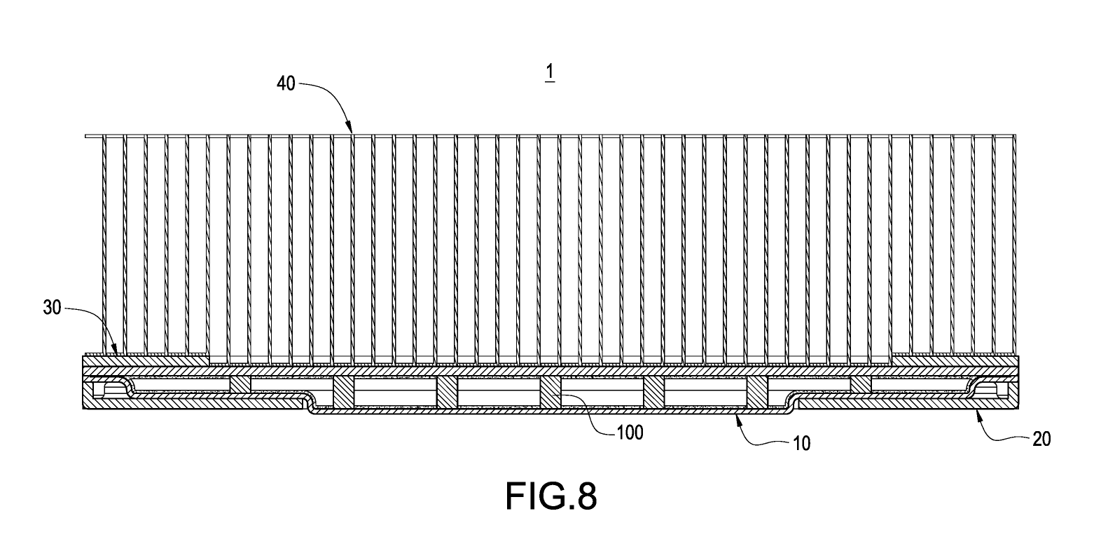

Further according to FIGS. 7 and 8 which are cross sectional views showing the assembled heat dissipation device having compact vapor chamber of the present disclosure from two directions. In the present embodiment, the heat dissipation member 40 is a heat dissipation fin stack, multiple yielding spaces 42 are defined on the heat dissipation member 40 at positions corresponding to the supporting frame 30, and the vapor chamber 10 is thereby directly contacted with the heat dissipation member 40. Accordingly, heat is rapidly conducted from the heat source member to the heat dissipation member 40 via the vapor chamber 10, and an efficiency of heat dissipation of the heat dissipation device 1 is therefore increased.

It is noted that, in the present embodiment, multiple supporting members 100 are arranged in the vapor chamber 10 (according to cylinders shown in the present embodiment, but the present disclosure should not be limited to the embodiment), the supporting members 100 are used for supporting the vapor chamber 10 to prevent the vapor chamber 10 from deformations. In addition, the supporting members 100 also increase heat condition or make heat condition uniform, and an efficiency of heat transfer of the vapor chamber 10 is thereby increased.

Although the present disclosure has been described with reference to the foregoing preferred embodiment, it will be understood that the disclosure is not limited to the details thereof. Various equivalent variations and modifications can still occur to those skilled in this art in view of the teachings of the present disclosure. Thus, all such variations and equivalent modifications are also embraced within the scope of the present disclosure as defined in the appended claims.

What is claimed is:

1. A heat dissipation device having compact vapor chamber, comprising:
a vapor chamber;
a supporting plate arranged on a surface of the vapor chamber, the supporting plate comprising a frame plate, an opening defined on the frame plate and a plurality of supporting ribs forming at a surrounding edge of the frame plate, the supporting rib being contacted with the surrounding edge of the vapor chamber, and a part of the vapor chamber being exposed through the opening;
a supporting frame, contacting with the other surface of the vapor chamber opposite to the supporting ribs, the supporting frame being extended from a side edge of the vapor chamber to another opposite side edge thereof; and
a heat dissipation member arranged on the supporting frame and contacted with the vapor chamber.

2. The heat dissipation device having compact vapor chamber according to claim 1, wherein a plurality of supporting members are arranged in the vapor chamber.

3. The heat dissipation device having compact vapor chamber according to claim 1, wherein the surface of the vapor chamber contacted with the supporting plate is of a step shape, a surface of the vapor chamber contacted with the supporting frame is of a flat shape, the vapor chamber comprises a first heat conductive portion, a second heat conductive portion surrounding the first heat conductive portion and a fixing portion at the surrounding edge of the vapor chamber, the first heat conductive portion is exposed through the opening, the second heat conductive portion is contacted with the frame plate, and a plurality of through holes is defined on the fixing portion.

4. The heat dissipation device having compact vapor chamber according to claim 3, wherein a plurality of first connecting holes are defined on the surrounding edge of the supporting plate at positions corresponding to the through holes.

5. The heat dissipation device having compact vapor chamber according to claim 4, wherein a protruding portion is formed on a surrounding edge of the supporting plate at each the first connecting holes.

6. The heat dissipation device having compact vapor chamber according to claim 1, wherein a surrounding edge of the frame plate is bent to form the supporting ribs of the supporting plate, and the supporting ribs are spaced apart from each other.

7. The heat dissipation device having compact vapor chamber according to claim 4, wherein a plurality of second connecting holes are defined on the supporting frame corresponding to positions of the through holes, a plurality of circular holes and a plurality of elongated holes are defined in each of the second connecting holes, and a breach gap is defined at a side of each elongated hole.

8. The heat dissipation device having compact vapor chamber according to claim 1, wherein the supporting frame is a frame of an “I” shape.

9. The heat dissipation device having compact vapor chamber according to claim 1, wherein the heat dissipation member is a heat dissipation fin stack, a plurality of yielding spaces are defined on the heat dissipation member at positions corresponding to the supporting frame.

10. The heat dissipation device having compact vapor chamber according to claim 1, wherein a plurality of opened portions are defined on the heat dissipation member at positions corresponding to the through holes.
